(19) United States
(12) Patent Application Publication
(10) Pub. No.: US 2010/0155228 A1
(43) Pub. Date: Jun. 24, 2010

(54) SPUTTERING APPARATUS AND METHOD OF MANUFACTURING ELECTRONIC DEVICE

(75) Inventors: Shoji Takiguchi, Tokyo (JP); Hideki Ueno, Kawasaki-shi (JP); Hiroshi Takano, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/639,220

(22) Filed: Dec. 16, 2009

(30) Foreign Application Priority Data
Dec. 24, 2008 (JP) 2008-327696

(51) Int. Cl. C23C 14/34

(52) U.S. Cl. 204/192.12; 204/298.08

(57) ABSTRACT

A sputtering apparatus includes a rotatable rotary member to which a target is attached, connection terminals, and feeding terminals. The connection terminals are arranged on the end portion of the rotary member in a direction along the axis of rotation of the rotary member, and are electrically connected to the target. The feeding terminals supply electric power to the target via the connection terminals. When the rotary member is rotated while the feeding terminals are in contact with the end portion of the rotary member, the electrical connection or insulation state between the feeding terminals and connection terminals is switched.

### BACKGROUND OF THE INVENTION

1. Field of the Invention

The present invention relates to a sputtering apparatus, which is applicable to deposition processing, surface treatment, and the like, and a method of manufacturing an electronic device.

2. Description of the Related Art

FIG. 6 is a sectional view showing the internal structure of a sputtering apparatus which is used to sputter a target, and is described in Japanese Patent Laid-Open No. 2000-265264. A sputtering apparatus shown in FIG. 6 has a rotatable cathode rotary member 70. Note that FIG. 6 shows a section perpendicular to the axis of rotation of the cathode rotary member 70. Cathodes 60 arranged on the side surfaces of the cathode rotary member 70 have a plurality of targets 72.

The cathode rotary member 70 has four side surfaces in its direction of rotation, and the cathodes 60 are arranged on the four side surfaces of the cathode rotary member 70. Each cathode 60 has a feeding connection terminal 75 which projects inside the cathode rotary member 70. In a sputter chamber (not shown), when each cathode 60 is set at a position facing a space 61 that forms a sputtering region, a target 72 provided on that cathode 60 opposes a substrate 73 supported on a substrate holder 66. This substrate 73 is a base substrate which is to undergo deposition processing.

At this time, a magnet 74 opposes the back surface of the cathode 60 (the inner surface of the cathode rotary member 70), and a feeding terminal 62 opposes the connection terminal 75 of that cathode 60. In this state, when a cylinder 63 is activated to move a movable shaft 64 forward, the magnet 74 is set at a position in the vicinity of the back surface of the cathode 60. When another cylinder 71 is activated to move another movable shaft 65 forward, the feeding terminal 62 is connected to the connection terminal 75. Electric power is supplied from the feeding terminal 62 to the cathode 60 via the connection terminal 75 connected to the feeding terminal 62. After that, a process gas is supplied to implement sputter deposition. Upon completion of the deposition, the cylinders 71 and 63 are activated to separate the magnet 74 and feeding terminal 62 from the cathode 60.

In Japanese Patent Laid-Open No. 2000-265264, the plurality of cathodes 60 are arranged on the side surfaces of the cathode rotary member 70, which is configured to be rotatable. With this structure, the sputtering apparatus which can sputter using the plurality of targets 72 can be made compact.

Currently, sputtering is often made by laying out a target (or cathode) at a predetermined angle with respect to a substrate which is to undergo deposition. In this way, the quality of films formed on a substrate is improved, as is known.

In a sputtering apparatus which makes deposition on a substrate such as a large glass substrate exceeding 1 m, a plurality of targets are often arranged to oppose a substrate. In this case, in order to uniform the film thickness distribution, a technique for adjusting each individual target to have a predetermined angle with respect to the substrate increasingly gains importance.

However, in the sputtering apparatus described in Japanese Patent Laid-Open No. 2000-265264, the connection terminals 75 and lines extending from them often suffer a load and twist due to the rotary motion of the cathode rotary member 70. This is because the lines project from the cathodes 60 in a direction toward the interior of the cathode rotary member 70, that is, in the radial direction of rotation. Especially, when the cathode rotary member 70 is rotated while the feeding terminal 62 and connection terminal 75 are in contact with each other, the load and twist imposed on the lines become larger. Owing to such load and twist, electric power cannot be stably supplied to the cathode 60.

In Japanese Patent Laid-Open No. 2000-265264, the feeding terminal 62 and connection terminal 75 are configured to be electrically connected only when the cathode 60 is laid out at a predetermined position. For this reason, it is difficult to sputter with an angle in place of a case in which the cathode faces the substrate.

From the aforementioned points, for the sputtering apparatus described in Japanese Patent Laid-Open No. 2000-265264, it is difficult to adjust the angle of the cathode or target with respect to a substrate.

### SUMMARY OF THE INVENTION

It is an object of the present invention to provide a sputtering apparatus which can solve at least one of the problems of the related art. An example of that object is to provide a sputtering apparatus which can adjust the angle of a target with respect to a substrate.

According to one aspect of the present invention, there is provided a sputtering apparatus comprising:

a rotatable rotary member to which a target is attached; connection terminals which are electrically connected to the target, and are arranged on an end portion of the rotary member in a direction along an axis of rotation of the rotary member; and

feeding terminals which supply electric power to the target via the connection terminals,

wherein when the rotary member is rotated while the feeding terminals are in contact with the end portion of the rotary member, an electrical connection or insulation state between the feeding terminals and the connection terminals is switched.

According to another aspect of the present invention, there is provided a method of manufacturing an electronic device, comprising:

the step of processing an object to be processed using the above-mentioned sputtering apparatus.

According to the arrangement of the present invention, instability of power supply can be eliminated, and the angle of a target with respect to a substrate can be adjusted.

Further features of the present invention will become apparent from the following description of exemplary embodiments with reference to the attached drawings.

### BRIEF DESCRIPTION OF THE DRAWINGS

FIG. 1 is a sectional view of a sputtering apparatus according to an embodiment of the present invention;

FIG. 2 is an enlarged view of a rotary member in a region bounded by the dotted line in FIG. 1;

FIG. 3 is a plan view of the rotary member viewed from a direction along an axis of rotation;

FIG. 4 is a view for explaining an allowable range of a connection position between a connection terminal and feeding terminal;

FIG. 5 is a top view of a sputtering apparatus according to an embodiment of the present invention;

FIG. 6 is a sectional view showing a schematic structure of a conventional sputtering apparatus; and

FIG. 7 is a view showing the sectional structure of an a-Si TFT (Thin Film Transistor).

### DESCRIPTION OF THE EMBODIMENTS

Embodiments of the present invention will be described hereinafter with reference to the drawings.

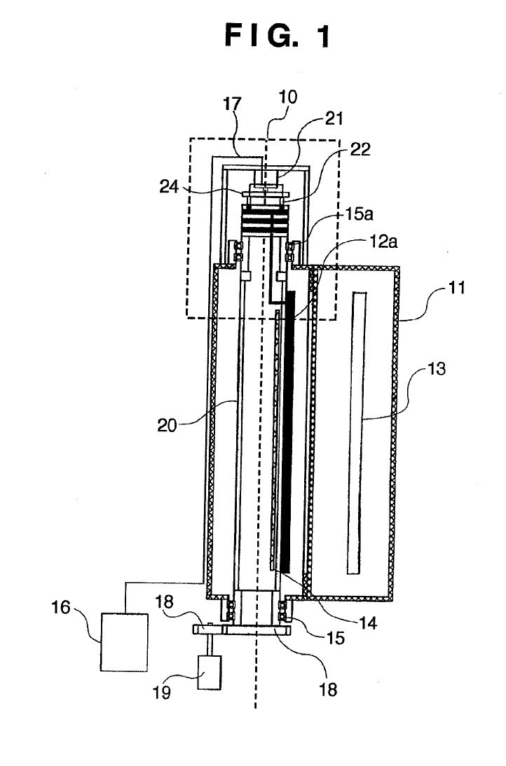

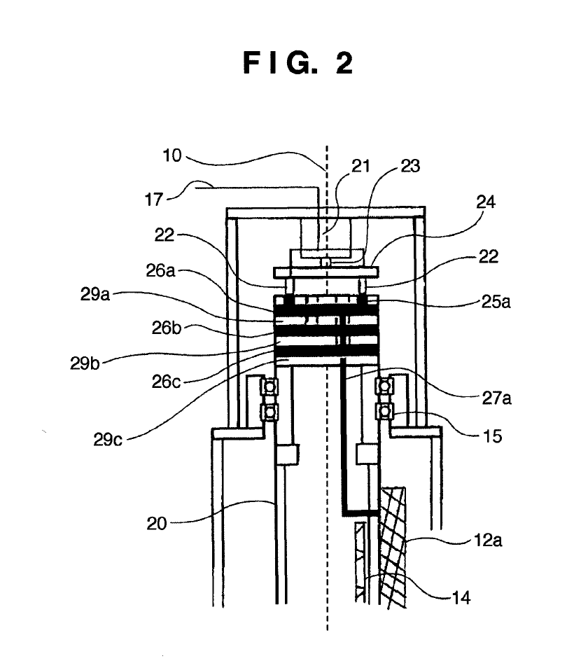

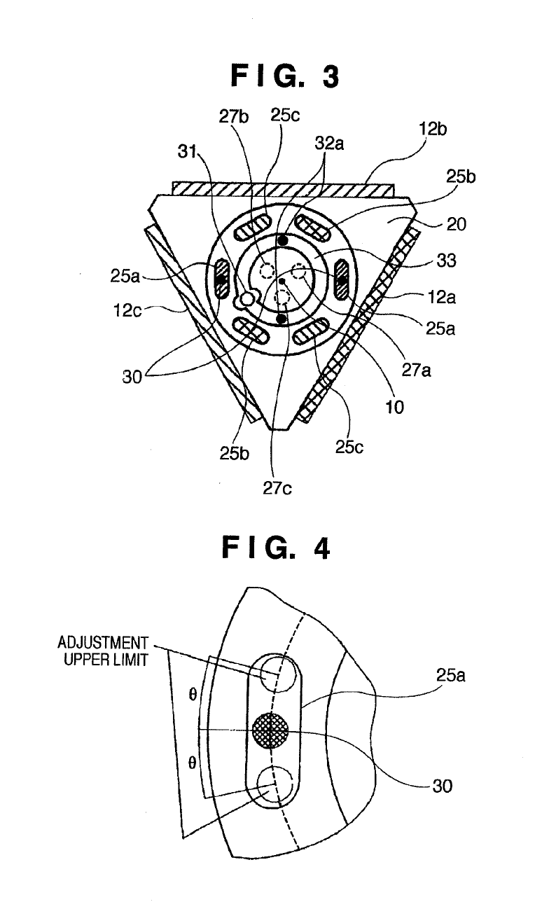

FIG. 1 is a sectional view of a sputtering apparatus according to an embodiment of the present invention. FIG. 2 is an enlarged view of the sputtering apparatus in a region bounded by the dotted line in FIG. 1. FIG. 3 is a plan view of a rotary member 20 viewed from a direction along an axis of rotation 10 of the rotary member 20.

In this embodiment, the sputtering apparatus has a chamber 11, rotatable rotary member 20, and substrate holder 13 which holds a substrate (not shown). The rotary member 20 has a nearly regular triangular prism shape, and a central axis of the triangular prism serves as an axis of rotation 10 of rotation. Three side surfaces along the axis of rotation 10 of this rotary member 20 respectively serve as cathodes. Targets 12a, 12b, and 12c as materials to be sputtered are detachably attached to these side surfaces.

The shape of the rotary member 20 is not limited to nearly the triangular prism, and is not particularly limited as long as targets can be attached. Therefore, the number of targets that can be attached to the rotary member 20 is not particularly limited. In this embodiment, a plurality of targets can be attached to the rotary member 20, but only one target is allowed to be attached.

The interior of the chamber 11 can be evacuated by an exhaust system mechanism (not shown). In the chamber 11, the substrate holder 13 which holds a substrate to be processed is arranged. By a plasma formed by a plasma generation mechanism (not shown) and a gas supply mechanism such as an Ar gas, a sputtering phenomenon occurs on a surface, facing the substrate holder 13, of the target 12a attached to the cathode. As a result, a thin film having, as major components, the composition of the target 12a is formed on the substrate attached to the substrate holder 13. During thin film formation by sputtering, the substrate may stand still or may move. In order to move the substrate, a convey mechanism (not shown) is used.

In the sputtering apparatus according to this embodiment, a magnet 14 for magnetron sputtering is arranged inside the rotary member 20. The magnet 14 is located on the back side of the target 12a (i.e., on a side opposite to the surface to be sputtered), which is attached to the side surface of the rotary member 20 and opposes the substrate holder 13. The magnet 14 may be configured to be reciprocally movable in a direction approximately perpendicular to the axis of rotation 10, that is, a direction along the surface of the target 12a (a direction orthogonal to the plane of paper of FIG. 1) which opposes the substrate holder 13. With this reciprocal movement, the use efficiency of a target and film thickness uniformity of a thin film formed on a substrate can be enhanced. The magnet 14 is arranged to generate a magnetic flux near the surface of the target and to concentrate plasma near the target.

In this embodiment, the rotary member 20 is configured to set the plurality of targets 12a, 12b, and 12c. These targets 12a, 12b, and 12c are attached to the side surfaces of the rotary member 20 along the axis of rotation 10. The rotary member 20 is rotated via a plurality of gears 18, a bearing 15, and the like using a motor 19 as a power source. With this rotation, the targets 12a, 12b, and 12c pivot about the axis of rotation 10 of the rotary member 20. Then, sputtering is done while an arbitrary one of the plurality of targets 12a, 12b, and 12c attached to the rotary member 20 opposes a substrate attached to the substrate holder 13.

In the vicinity of the end face of the rotary member 20 in a direction along the axis of rotation 10 of the rotary member 20, a cylinder 21 and feeding terminal fixing plate 24 fixed to the cylinder 21 are arranged. A feeding terminals 22 are arranged on the feeding terminal fixing plate 24. The feeding terminals 22 are configured to be reciprocally movable. More specifically, the cylinder 21 drives to reciprocally move the feeding terminals 22, so that the feeding terminals 22 are in contact with or are spaced apart from the end portion of the rotary member 20 in the direction along the axis of rotation 10.

The feeding terminals 22 are connected to a power source 16 via a high-voltage line 17. In this embodiment, the power source 16 is a DC power source, but a DC pulse power source or AC power source may be used. When the feeding terminals 22 are in contact with the rotary member 20, electric power is supplied to the target 12 attached to the cathode via a line formed on the rotary member 20.

A structure for supplying electric power from the power source 16 from the rotary member 20 to the target 12a, 12b, or 12c will be described below with reference to FIG. 2. Three pairs of connection terminals 25a, 25b, and 25c are exposed from the end portion of the rotary member 20 in the direction along the axis of rotation 10 (see FIG. 3). The respective pairs of connection terminals 25a, 25b, and 25c are respectively electrically connected to the targets 12a, 12b, and 12c attached to the rotary member 20. Different pairs of connection terminals are never connected to the feeding terminals 22 at the same time. That is, the feeding terminals 22 supply electric power to only one target at one time. Electric power is supplied from the feeding terminals 22 to the target via the connection terminals connected to the feeding terminals 22.

With this arrangement, the connection terminals 25a, 25b, and 25c are exposed from the end portion of the rotary member 20 in the direction along the axis of rotation 10 of the rotary member 20. The feeding terminals 22 are brought into contact with the exposed connection terminals 25a, 25b, or 25c. The connection terminals 25a, 25b, and 25c are exposed from the end portion of the rotary member 20, and lines connected to the connection terminals do not project from the rotary member 20. For this reason, even when the rotary member 20 is rotated about the axis of rotation 10 to make an angle with respect to a substrate (not shown) or to change the type of target or the like, a load and twist of the connection terminals 25a, 25b, and 25c and lines can be suppressed. Especially, when the connection terminals 25a, 25b, and 25c are embedded in the end portion of the rotary member 20, a load on the connection terminals 25a, 25b, and 25c can be further reduced.

The feeding terminals 22 are configured to be reciprocally movable in the direction along the axis of rotation 10, and can contact or be separated from the end portion of the rotary member 20. More specifically, a cylinder translation unit 23 transfers power of the cylinder 21 to the feeding terminal fixing plate 24. Then, the feeding terminals 22 are movable in the direction along the axis of rotation 10.

On the feeding terminal fixing plate 24 fixed to the cylinder 21, two feeding terminals 22 are equipped at positions which oppose each other to sandwich the axis of rotation 10 between them. These feeding terminals 22 are connected to the power source 16 via the high-voltage line 17.

On the other hand, the three pairs of connection terminals 25a, 25b, and 25c, which are electrically connected to electrodes 26a, 26b, and 26c, are formed on the end portion of the rotary member 20 in the direction along the axis of rotation 10. Each pair (two) of the respective pairs of connection terminals 25a, 25b, and 25c are laid out on the circumference of a circle having the center on the axis of rotation 10 of the rotary member 20. The connection terminals of each pair can be simultaneously connected to the feeding terminals 22.

For example, one target 12a attached to the rotary member 20 is electrically connected to the electrode 26a via a line 27a, which is not electrically connected to the electrodes 26b and 26c of other targets 12b and 12c.

The targets 12b and 12c other than one target 12a are respectively electrically connected to the corresponding electrodes 26b and 26c. However, the electrodes 26a, 26b, and 26c are insulated from each other by insulators 29a, 29b, and 29c. The connection terminals 25a, 25b, and 25c, which are respectively electrically connected to the electrodes 26a, 26b, and 26c, are exposed from the end portion of the rotary member 20 in the direction along the axis of rotation 10 (see FIG. 3).

In this manner, the respective pairs of connection terminals 25a, 25b, and 25c are electrically connected to only the corresponding targets (the connection terminals 25a in case of the target 12a). In this embodiment, each pair includes two connection terminals. However, at least one connection terminal need only correspond to each target.

In this embodiment, the two connection terminals 25a are arranged in correspondence with one target 12a. These two connection terminals 25a are laid out at positions rotated through 180° about the axis of rotation 10. As a result, a force acting from the cylinder translation unit 23 to the connection terminals 25a via the feeding terminals 22 is uniformed.

FIG. 3 is a plan view of the rotary member 20 viewed from the direction along the axis of rotation 10. That is, FIG. 3 shows the end portion of the rotary member 20 in a direction of the axis of rotation. The three pairs of connection terminals 25a, 25b, and 25c, which are respectively electrically connected to the electrodes 26a, 26b, and 26c, are exposed from the end portion of the rotary member 20. The respective connection terminals 25a, 25b, and 25c are laid out on the circumference of a circle having the center on the axis of rotation 10 of the rotary member 20. That is, all the connection terminals 25a, 25b, and 25c are exposed at positions spaced apart by nearly equal distances from the axis of rotation. The end portion of the rotary member 20 where the three pairs of connection terminals are laid out is spaced apart from the chamber 11 that can be evacuated via the bearing 15, and is arranged under the atmospheric pressure.

With the above arrangement, when the rotary member 20 is rotated while the feeding terminals 22 are in contact with the end portion of the rotary member 20, the electrical connection or insulation state between the feeding terminals 22 and connection terminals 25a, 25b, and 25c is switched. With this arrangement, when the rotary member 20 is rotated, an angle of the target attached to the cathode with respect to a substrate can be adjusted.

A ground ring 33, which is connected to a grounded ground line 31, is arranged on the end portion of the rotary member 20 in the direction of the axis of rotation. The ground ring 33 has a concentric circular shape inside the circumference of the circle from which the connection terminals 25a, 25b, and 25c are exposed. FIG. 3 also shows ground positions 32a of the feeding terminals 22 on the ground ring 33 when the feeding terminals 22 are in contact with the connection terminals 25a. In the same manner as in the case in which the feeding terminals 22 press the connection terminals 25a, 25b, or 25c, the two ground positions 32 are set to be symmetrical about the axis of rotation 10, so as to assure high contact stability.

As described above, in this embodiment, when the feeding terminals 22 supply electric power to a target, they contact the two connection terminals and the two positions of the ground ring, that is, a total of four positions. However, the present invention is not limited to these positions.

Although not exposed from the end portion of the rotary member 20, FIG. 3 also shows the positions of lines 27a, 27b, and 27c, which respectively connect the targets 12a, 12b, and 12b, and the connection terminals 25a, 25b, and 25c, using the dotted lines, for reference.

The connection terminals 25a, 25b, and 25c are arranged on the circle having, as the center, the axis of rotation 10 of the rotary member 20. Since the lines from the cathodes to which respective targets are detachable do not project, a load and twist of the lines can be suppressed even when the rotary member 20 is rotated, and electric power can be stably supplied to the target.

The ground ring 33 as a ground terminal is formed to have a circular shape having, as the center, the axis of rotation 10 of the rotary member 20. In this embodiment, for example, the ground ring 33 is arranged on the inner side of the connection terminals.

The connection terminals 25a, 25b, and 25c are arranged on the circumference of the circle having, as the center, the axis of rotation 10 of the rotary member 20. Each of the connection terminals 25a, 25b, and 25c preferably has a shape extending along the circumference of a circle, which has the axis of rotation 10 as the center and a predetermined center angle θ, that is, along a direction of rotation of the rotary member 20. Then, the contact positions between the connection terminals 25a, 25b, and 25c and feeding terminals 22 can have a spread (predetermined range). For this reason, the connection terminals 25a, 25b, and 25c and feeding terminals 22 can be prevented from being displaced as a cause of unstable power supply. Therefore, electric power can be more stably supplied to the cathode.

The connection terminals 25a, 25b, and 25c connected to the respective targets 12a, 12b, and 12c are laid out on the end face of the rotary member 20 in the direction along the axis of rotation 10 to be juxtaposed in the direction of rotation. Then, upon rotation of the rotary member 20, the connection terminals to be connected to the feeding terminals 22 can be switched.

The sputtering apparatus of this embodiment has the three pairs of connection terminals 25a, 25b, and 25c in which two connection terminals correspond to one target. In this case, the connection terminals on the circumference of the circle having the axis of rotation 10 as the center can be laid out at every 60° (360÷3 (the number of targets)÷2 (the number of connection terminals per target)).

Gaps have to be assured between the neighboring connection terminals 25a, 25b, and 25c so as to be insulated from each other. Even in this case, the connection terminals 25a, 25b, and 25c can have a maximum rotation angle less than 60° about the axis of rotation 10. In this way, power supply can be stabilized, and an allowable range of angle adjustment of the cathode (or target) with respect to a substrate can be broadened.

FIG. 4 shows an allowable range of the pressing position of each feeding terminal 22 in association with the connection terminals 25a, 25b, or 25c shown in FIG. 3. The respective connection terminals 25a, 25b, and 25c extend on the end portion of the rotary member 20 along the direction of rotation of the rotary member 20. FIG. 4 expresses an allowable range, in which connection of each of the connection terminals 25a, 25b, and 25c extending along the direction of rotation is maintained, using deviation angles θ from a central position 30 and pressing positions as adjustment upper limits.

Since the connection terminals 25a, 25b, and 25c are formed along the direction of rotation in this way, power supply becomes rarely unstable due to displaced connection positions between the connection terminals 25a, 25b, and 25c and feeding terminals 22, and more stable power supply can be realized. Furthermore, an angle of the target attached to the cathode with respect to a substrate can be arbitrarily adjusted within the allowable range, and the process conditions of sputtering can be expanded.

In this embodiment, the connection terminals 25a, 25b, and 25c extend along the direction of rotation of the rotary member 20. However, at least one of each feeding terminal and connection terminal need only be extended along the direction of rotation of the rotary member. Even in this case, the same effect as that obtained when the connection terminals extend in the direction of rotation can be obtained.

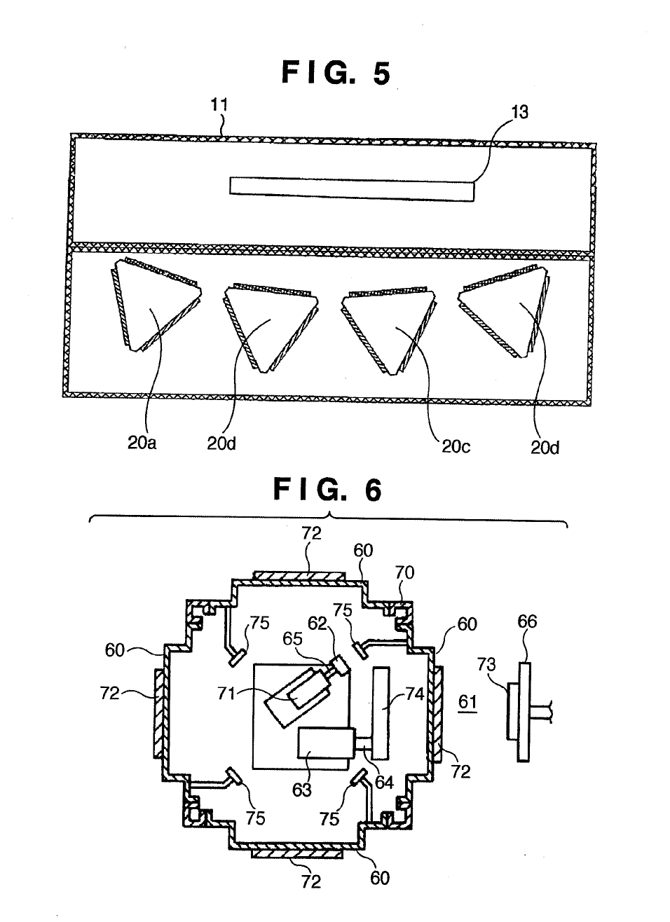

FIG. 5 is a top view (a plan view viewed from the direction along the axis of rotation) of a sputtering apparatus according to another embodiment of the present invention. In the sputtering apparatus of this embodiment, four rotary members 20a, 20b, 20c, and 20d each of which has the same arrangement as the rotary member shown in FIG. 1 are arranged in a chamber 11. The four rotary members 20a, 20b, 20c, and 20d are juxtaposed. One of cathodes of the respective rotary members 20a, 20b, 20c, and 20d can oppose a substrate holder 13. In this embodiment, the number of rotary members is four, but it is not particularly limited.

In the above embodiments, a target is detachably attached to the cathode rotary member 20. Alternatively, a target may be integrally attached to the cathode rotary member 20.

In the above embodiments, the magnetron sputtering apparatus has been exemplified in detail. However, the sputtering apparatus of the present invention may be a diode sputtering apparatus, and the present invention is not limited to such sputtering apparatuses.

The preferred embodiments of the present invention have been presented, and have been described in detail. However, the present invention is not limited to the above embodiments, and various changes and modifications can be made without departing from the scope of the invention.

(Method of Manufacturing Electronic Device)

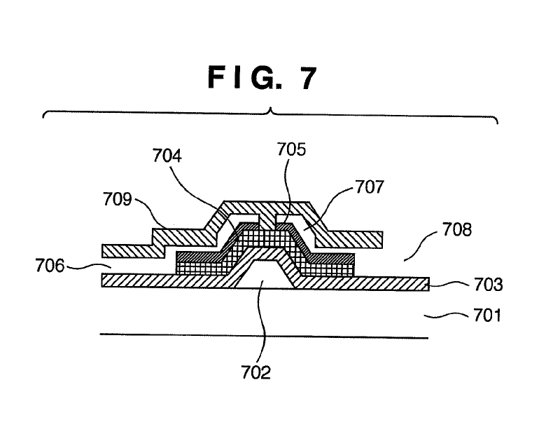

A method of manufacturing a display element using the sputtering apparatus of the present invention as an example of an electronic element will be described below with reference to FIG. 7. FIG. 7 shows the sectional structure of an a-Si TFT (Thin Film Transistor). In the method of manufacturing a display element, a deposition apparatus is used in an array manufacturing process and BM (Black Matrix) manufacturing process.

For example, in the array manufacturing process, transistors and interconnects are formed on a substrate 701. Processes that mainly use sputtering in association with deposition are following processes a, d, and e, and films are sequentially stacked in the following processes a to f.

Process a: a gate electrode (Mo, Al, etc.) 702

Process b: a gate insulating film (SiNx, etc.) 703

Process c: semiconductor layers (a-Si, a-Si(n+)P, etc.) 704 and 705

Process d: source/drain electrodes (Mo, Al, etc.) 706 and 707

Process e: a transparent electrode (ITO, etc.) 708

Process f: a protective film (SiNx, etc.) 709

In the sectional structure of the TFT shown in FIG. 7, in the processes a, d, and e, thin films suited to a display element were formed by adjusting respective parameters such as sputtering gases, degrees of vacuum, substrate temperatures, discharge electric powers, and discharge times in correspondence with target seeds as thin film material sources.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-327696, filed Dec. 24, 2008, which is hereby incorporated by reference herein in its entirety.

What is claimed is:

1. A sputtering apparatus comprising:
a rotatable rotary member to which a target is attached;
connection terminals which are electrically connected to the target, and are arranged on an end portion of said rotary member in a direction along an axis of rotation of said rotary member; and
feeding terminals which supply electric power to the target via said connection terminals,
wherein when said rotary member is rotated while said feeding terminals are in contact with the end portion of said rotary member, an electrical connection or insulation state between said feeding terminals and said connection terminals is switched.

2. The apparatus according to claim 1, wherein at least one of the feeding terminal and the connection terminal extends along a direction of rotation of said rotary member.

3. The apparatus according to claim 1, wherein said feeding terminals are configured to be reciprocally movable, and to be in contact with or separated from the end portion of said rotary member.

4. The apparatus according to claim 1, wherein said rotary member is configured to attach a plurality of targets,
the connection terminals, which are respectively connected to the targets, are laid out on the end portion of said rotary member, and
the respective connection terminals are arranged in a direction of rotation of said rotary member.

5. The apparatus according to claim 4, wherein the connection terminals to be connected to said feeding terminals are switched upon rotation of said rotary member.

6. The apparatus according to any one of claims 1 to 5, wherein a magnet which generates a magnetic flux on a surface of the target attached to said rotary member is arranged inside said rotary member.

7. The apparatus according to claim 1, wherein at least two rotary members equivalent to said rotary member are arranged.

8. The apparatus according to claim 1, further comprising a holder which is arranged to oppose a surface, to which the target is attached, of said rotary member, and holds a substrate to be processed.

9. A method of manufacturing an electronic device, comprising:
the step of processing an object to be processed using a sputtering apparatus according to claim 1.
